(19) United States
(12) Patent Application Publication
(10) Pub. No.: US 2008/0073799 A1
(43) Pub. Date: Mar. 27, 2008

(54) MOULD HAVING NANO-SCALED HOLES

(75) Inventors: DING WANG, Beijing (CN); PENG-CHENG SONG, Beijing (CN); CHANG-HONG LIU, Beijing (CN); SHOU-SHAN FAN, Beijing (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignees: TSINGHUA UNIVERSITY, Beijing (CN); HON HAI PRECISION INDUSTRY CO., LTD., Tu-Cheng (TW)

(21) Appl. No.: 11/617,971

(22) Filed: Dec. 29, 2006

(30) Foreign Application Priority Data
Sep. 22, 2006 (CN) 200610062719.3

(51) Int. Cl. H01L 23/48

(52) U.S. Cl. 257/783

(57) ABSTRACT

A mould includes a base having a first surface and a second surface opposite to the first surface; and a plurality of nano-scaled holes defined through the base. Each nano-scaled hole extends from the first surface to the second surface of the base and is parallel to each other and oriented substantially perpendicular to the first and second surface.

### RELATED APPLICATIONS

This application is related to commonly-assigned application entitled, “METHOD FOR MANUFACTURING MOULD HAVING NANO-SCALED”, filed (Atty. Docket No. US11275), the content of which is hereby incorporated by reference thereto.

### BACKGROUND

1. Field of the Invention

The invention relates generally to moulds having holes and, more particularly, to a mould having nano-scaled holes.

2. Discussion of Related Art

At present, the manufacturing of mould are progressing toward the large-scale processing with high levels of precision. In the field of large-scale processing, such as extrusion moulds for manufacturing large whole walls for use in automobile or aircraft manufacture, the manufacturing process thereof has become relatively mature. However, in the field of high precision processing, the need for nano-scale products is rising rapidly. Application of advanced nano-scale manufacturing technology in the manufacturing of moulds has become an area of great interest. This application can make the industrialization of high precision nano-scale processing possible.

In theory, nano technology can be widely applied in processing. A related assumed processing method based on the assembly of nanoparticles is known. This assumed processing method assumes the molecules are arranged according to the shapes of the products. This assumed processing method does not need to use moulds, however, this is unfeasible in practice. This is because that the arrangement of the molecules is executed using a scanning tunneling microscopy (STM) or atomic force microscopy (AFM), requiring overly high levels of precision. Therefore, the assumed processing method cannot be used to mass-produce nano-scale products.

What is needed, therefore, is a mould having nano-scale holes, the mould is suitable for mass producing nano-scale products.

### SUMMARY

A mould includes a base having a first surface and a second surface opposite to the first surface; and a plurality of nano-scaled holes defined through the base. Each nano-scaled hole extends from the first surface to the second surface of the base and are oriented parallel to each other and substantially perpendicular to the first and second surfaces.

Other advantages and novel features of the present mould having nano-scaled holes will become more apparent from the following detailed description of preferred embodiments when taken in conjunction with the accompanying drawings.

### BRIEF DESCRIPTION OF THE DRAWINGS

Many aspects of the present mould having nano-scaled holes can be better understood with reference to the following drawings. The components in the drawings are not necessarily to scale, the emphasis instead being placed upon clearly illustrating the principles of the present mould having nano-scaled holes.

FIG. 1 is a schematic side elevation of a mould having nano-scaled holes;

FIG. 2 is a flow chart in accordance with a method for manufacturing the mould of FIG. 1; and

FIG. 3 is a schematic side elevation of an array formed by the mould of FIG. 1.

Corresponding reference characters indicate corresponding parts throughout the several views. The exemplifications set out herein illustrate at least one preferred embodiment of the present mould having nano-scaled holes, in one form, and such exemplifications are not to be construed as limiting the scope of the invention in any manner.

### DETAILED DESCRIPTION OF PREFERRED EMBODIMENTS

Reference will now be made to the drawings to describe embodiments of the present method for manufacturing a mould having nano-scaled holes, in detail.

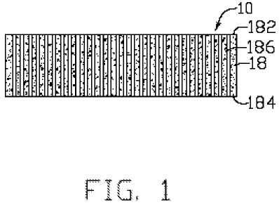

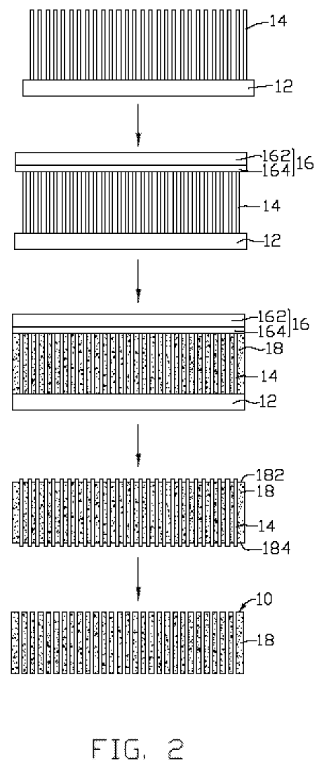

FIG. 1 is schematic side elevation of a mould 10, in accordance with a first exemplary embodiment of the present device. Referring to FIG. 2, the mould 10 has a thickness thereof being about 0.1 to 1 millimeter and includes a matrix material 18 and a plurality of nano-scaled holes 186 defined therethrough. The matrix material 18 is a film and includes a first surface 182 and a second surface 184 opposite to the first surface 182. The nano-scaled holes 186 are parallel to each other and substantially perpendicular to the first and second surface 182, 184 of the matrix material 18. Furthermore, the nano-scaled holes 186 extend from the first surface 182 to the second surface 184 of the matrix material 18 and run through the matrix material 18. In the preferred embodiment, a radius of the nano-scaled holes 186 is in the range from 10 to 100 nanometers, and a distance between every two nano-scaled holes 186 is in the range from 20 to 200 nanometers.

Referring to FIG. 2, a method for manufacturing the present mould 10 is shown. The method includes the steps of:

(a) providing a plurality of carbon nanotubes 14;

(b) forming at least one protective layer 16 on at least one end of the carbon nanotubes 14;

(c) injecting a solution of a matrix material 18 or a melted matrix material 18 into the carbon nanotubes 14, or immersing the carbon nanotubes 14 in a solution of a matrix material 18 or a melted matrix material 18, and solidifying the matrix material 18;

(d) removing the protective layer 16 thereby forming a composite structure having the carbon nanotubes 14 and the solidified matrix material 18; and

(e) removing the carbon nanotubes 14 thereby forming the mould 10 having the nano-scaled holes 186.

In step (a), the carbon nanotubes 14 are in the form of an array made by means of chemical vapor deposition (CVD), plasma enhanced chemical vapor deposition (PECVD) or plasma assistant hot-filament chemical vapor deposition (PAHFCVD). The carbon nanotubes 14 can be multi-walled or signal-walled and are formed on a substrate 12 with the first end thereof engaging with the substrate and the second end opposite to the first end. The substrate can be peeled from the carbon nanotubes easily and doesn't affect the distribution of the carbon nanotubes 14.

The array of carbon nanotubes 14 is formed by the following steps: (a1) coating a catalyst film on the substrate 12; (a2) oxidizing the catalyst film at a temperature of about 300° C. to obtain catalyst particles; and (a3) placing the substrate 12 with the catalyst particles disposed thereon in a reaction furnace, and providing a carbon source gas in the reaction furnace at a temperature of 700-10000° C. to grow the array of carbon nanotubes 14.

In step (a1), the catalyst film can be made of iron (Fe), cobalt (Co), nickel (Ni), or an alloy thereof. In the preferred embodiment, the catalyst film is made of iron (Fe) and a thickness thereof is about 5 nanometers. In step (a3), the carbon source gas can be acetylene or ethene. A diameter of the carbon nanotubes is in the range from 1 to 100 nanometers. A height of the carbon nanotubes 14 can be controlled by controlling the growth time thereof. The height of the array of carbon nanotubes 14 is generally in the range from 1 to 100 micrometers. In the preferred embodiment, the height of the carbon nanotubes 14 is about 100 micrometers.

Step (b) includes the steps of: (b1) providing a base 162 having a layer of pressure sensitive adhesive 164; and (b2) pressing the layer of pressure sensitive adhesive 164 of the base 162 to the second end of the array of carbon nanotubes 14 to form the protective layer 16, and the substrate 12 acts as another protective layer. Alternatively, in step (b), a pair of protective layers 16 can be formed on opposite ends of the array of carbon nanotubes 14. After the protective layer 16 is formed on the second end of the array of carbon nanotubes 14, the substrate 12 is peeled from the first end of the array of carbon nanotubes 14, and steps (b1) and (b2) are repeated with the first end of the array of carbon nanotubes 14 to form another protective layer 16 thereon.

In the above-described step (b), the base 162 can be a polyester chip, the layer of pressure sensitive adhesive 164 can be the YM881. Furthermore, a thickness of the protective layer 16 is about 0.05 micrometers.

In step (c), the solidifying process is executed in vacuum for about 24 hours. The matrix material 18 is an anti-corrosion macromolecule material. The matrix material 18 is selected from the group consisting of poly-tetra-fluoro-ethylene (PTFE), silicon rubber, polyester, polyvinylchloride (PVC), polyvinylalcohol (PVA), polyethylene (PE), polypropylene (PP), epoxy resin (EP), polycarbonate (PC), and polyoxymethylene (POM). In the preferred embodiment, the matrix material 18 is poly-tetra-fluoro-ethylene (PTFE).

Furthermore, a step of vacuumizing is further executed before step (c). The process of vacuumizing is executed for about 30 minutes in order to discharge the air among the carbon nanotubes 14. This vacuumizing helps injection of the solution of the matrix material 18 or the melted matrix material 18.

In step (d), the base 162 can be peeled directly and the layer of pressure sensitive adhesive 164 can be dissolved by xylene, ethyl acetate or petroleum aether. Furthermore, when the substrate 12 acts as another protective layer, the substrate 12 can be peeled away directly. After that, a first surface 182 and an opposite second surface 184 of the matrix material 18 are exposed, and the first and second ends of the carbon nanotubes 14 are also exposed and extend from the first and second surfaces 182, 184 of the matrix material 18 respectively. Therefore, in the formed composite structure the solidified matrix material 18 and the carbon nanotubes 14 extend from the first and second surfaces 182, 184 of the matrix material 18 respectively.

In step (e), the carbon nanotubes are removed by a strong acid solution or a strong oxidated solution. In the preferred embodiment, a mixed solution of oil of vitriol and thick nitric acid with the weight percentage thereof being about 3:1 is adopted, and the mixed solution is reflowed into the composite structure for about 30 minutes to 2 hours thus removing the carbon nanotubes using the erosive effect of the oil of vitriol and thick nitric acid. Therefore, the anti-corrosion matrix material 18 with the carbon nanotubes removed therefrom is formed as the mould 10 having a plurality of nano-scaled holes.

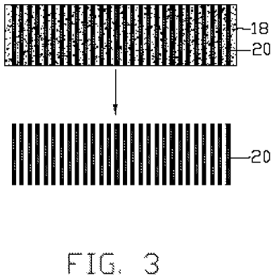

Referring to FIG. 3, an gold array 20 formed by the mould 10 of FIG. 2 is shown. Firstly, a solution of gold or a melted gold is filled into the mould 10. Secondly, the mould 10 is removed by means of chemical eroding or high temperature calcinating thereby forming nano-scaled gold array 20. It can be understood that arrays of other material can also be formed by the mould 10 of FIG. 1 corresponding to the above-described steps. Furthermore, the mould 10 can also be applied in the impressing filed to form nano-scaled raised structures on a surface of chosen material.

Finally, it is to be understood that the above-described embodiments are intended to illustrate rather than limit the invention. Variations may be made to the embodiments without departing from the spirit of the invention as claimed. The above-described embodiments illustrate the scope of the invention but do not restrict the scope of the invention.

What is claimed is:

1. A mould comprising:
a base having a first surface and a second surface opposite to the first surface; and
a plurality of nano-scaled holes defined through the base, each nano-scaled hole extending from the first surface to the second surface of the base and being parallel to each other and substantially perpendicular to the first and second surface.

2. The mould as claimed in claim 1, wherein the base is a polymer film.

3. The mould as claimed in claim 1, wherein a radius of the nano-scaled holes is in the range from 10 to 100 nanometers.

4. The mould as claimed in claim 1, wherein a distance between every two adjacent nano-scaled holes is in the range from 20 to 200 nanometers.

5. The mould as claimed in claim 1, wherein a thickness of the base is in the range from 0.1 to 1 millimeter.

6. The mould as claimed in claim 1, wherein the base is made of a material selected from the group consisting of poly-tetra-fluoro-ethylene, silicon rubber, polyester, polyvinylchloride, polyvinylalcohol, polyethylene, polypropylene, epoxy resin, polycarbonate, and polyoxymethylene.
